(19) United States
(12) Patent Application Publication
(10) Pub. No.: US 2026/0059827 A1
(43) Pub. Date: Feb. 26, 2026

(54) CFET WITH VIA FUSE STRUCTURE AND METHOD

(71) Applicant: Taiwan Semiconductor Manufacturing Co., Ltd., Hsinchu (TW)

(72) Inventors: Meng-Sheng Chang, Chu-bei City (TW); Chia-En Huang, Xinfeng Township (TW); I-Hsin Yang, Kaohsiung City (TW)

(21) Appl. No.: 19/268,569

(22) Filed: Jul. 14, 2025

Related U.S. Application Data
(63) Continuation of application No. 18/498,697, filed on Oct. 31, 2023.
(60) Provisional application No. 63/487,033, filed on Feb. 27, 2023.

(51) Int. Cl. H10D 64/01; H10D 30/01; H10D 30/62; H10D 30/67; H10D 62/10; H10D 84/85; H10D 88/00

(52) U.S. Cl. CPC H10D 64/017; H10D 30/024; H10D 30/6211; H10D 30/6755; H10D 62/118; H10D 84/856; H10D 88/00

(57) ABSTRACT

An embodiment includes a method including forming a first conductive feature and a second conductive feature in a substrate. The method also includes forming a first complementary field-effect transistor (CFET) over the substrate, the forming including forming a first lower transistor including a first gate and a first source/drain region. The method also includes forming a first upper transistor including a second gate and a second source/drain region, the first upper transistor overlapping the first lower transistor. The method also includes forming a conductive via fuse connected to the first conductive feature and the second source/drain region.

### PRIORITY CLAIM AND CROSS-REFERENCE

This application is a continuation of U.S. patent application Ser. No. 18/498,697, filed Oct. 31, 2023, entitled “CFET With Via Fuse Structure and Method,” which claims the benefit of the following provisionally filed U.S. patent application: Application No. 63/487,033, filed on Feb. 27, 2023, and entitled “Deep Via-Fuse Memory in CFET Process” which applications are hereby incorporated herein by reference.

### BACKGROUND

Complementary Field-Effect Transistors (CFETs) are being developed to meet the increasing demanding requirement for increasing the density of transistors in integrated circuits. A CFET includes a bottom transistor and a top transistor overlapping the top transistor. The bottom transistors and top transistors of multiple CFETs may be interconnected to form circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of a Complementary Field-Effect Transistor (CFET) and a through-via in accordance with some embodiments.

FIGS. 2-10, 11A, 11B, 11C, 12A, 12B, 12C, 13A, 13B, 13C, 14A, 14B, 14C, 15A, 15B, 15C, 16A, 16B, 16C, 17-19, 20A, 20C, 21A, 21C, 22A, 22C, 23A, 23C, and 24 illustrate cross-sectional views in the formation of CFETs and a conductive via fuse in a sequential CFET formation process in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Complementary Field-Effect Transistors (CFETs) and a via fuse and the method of forming the same are provided. In accordance with some embodiments, a via fuse is formed, which is sometimes referred to as a deep via fuse, and the via fuse is included in a memory cell area of the device, such as a static random-access memory (SRAM) memory array area. One or more interlayer dielectric layers are etched to form an opening therein, followed by filling the opening to form a via fuse, which may be formed of metal. The via fuse may extend from a source/drain region to a buried conductive region in a substrate. The via fuse may be used as a fuse to remove or isolate devices from functional portions of a circuit. By including the via fuse in the CFET device, and in some embodiments in the memory cell area of the device, the area required for the fuses can be reduced and can save as much as 30% area over conventional fuse layouts.

The embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

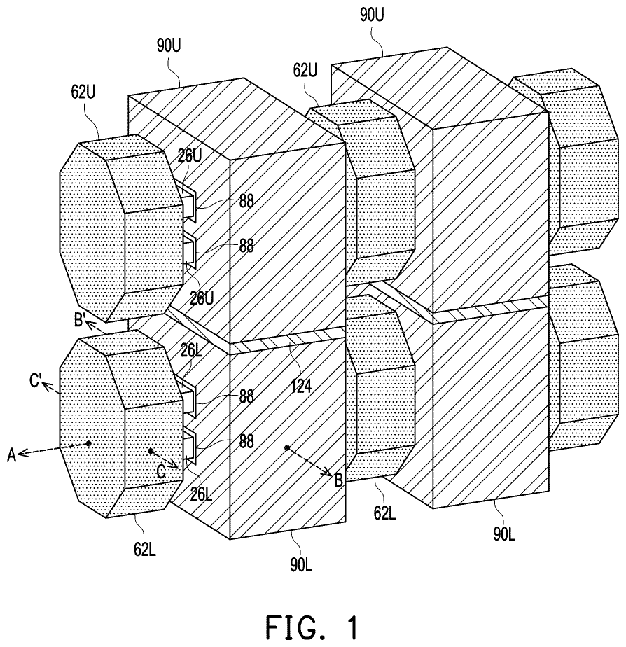

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity. The CFETs include multiple vertically stacked FETs. For example, a CFET may include a lower nanostructure-FET (transistor) 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26 (including lower semiconductor nanostructures 26L and upper semiconductor nanostructures 26U), wherein the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U.

Gate dielectrics 88 encircle the respective semiconductor nanostructures 26. Gate electrodes 90 (including a lower gate electrode 90L and an upper gate electrode 90U) are formed on the gate dielectrics 88. Source/drain regions 62 (including lower source/drain regions 62L and upper source/drain regions 62U) are disposed on opposing sides of the gate dielectrics 88 and the respective gate electrodes 90. The source/drain region may refer to a source or a drain, individually or collectively dependent upon the context. Isolation features (not shown) may be formed to separate desired ones of the source/drain regions 62 and/or desired ones of the gate electrodes 90.

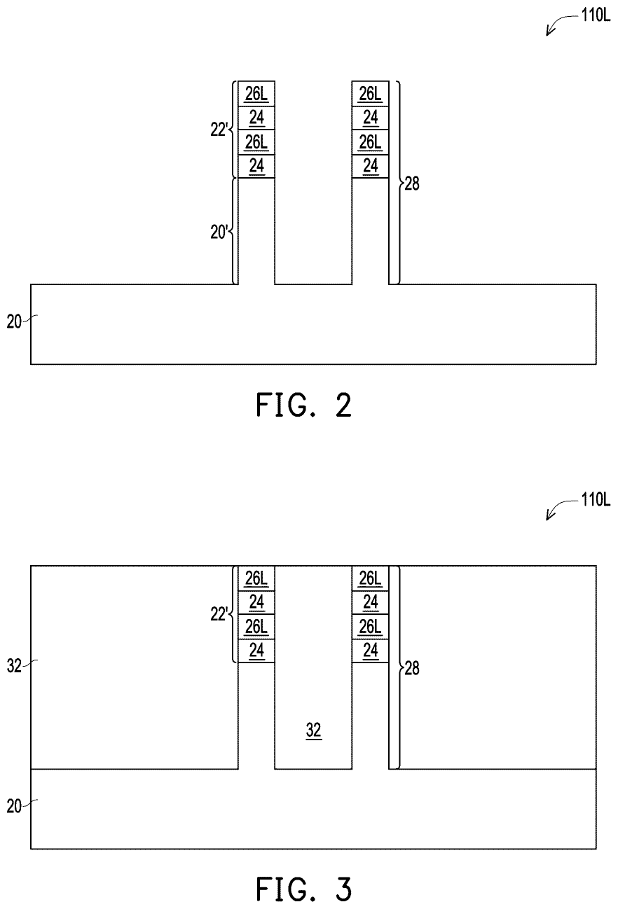

FIGS. 2-10, 11A, 11B, 11C, 12A, 12B, 12C, 13A, 13B, 13C, 14A, 14B, 14C, 15A, 15B, 15C, 16A, 16B, 16C, 17-19, 20A, 20C, 21A, 21C, 22A, 22C, 23A, 23C, and 24 illustrate the cross-sectional views of intermediate stages in the formation of CFETs and a conductive via fuse in accordance with some embodiments of the present disclosure. The formation of the CFETs according to these figures is referred to as a sequential formation process since the lower nanostructure-FETs 10L are formed first, and then upper nanostructure-FETs 10U are formed over the already formed lower nanostructure-FETs 10L. In subsequent discussion, unless specified otherwise, the figures having digits followed by letter “A” may illustrate the vertical cross-sectional views along a similar cross-section as vertical reference cross-section A-A′ in FIG. 1. The figures having digits followed by letter “B” may illustrate the cross-sectional views along a similar cross-section as the vertical reference cross-section B-B′ in FIG. 1. The figures having digits followed by letter “C” may illustrate the cross-sectional views along a similar cross-section as the vertical reference cross-section C-C′ in FIG. 1.

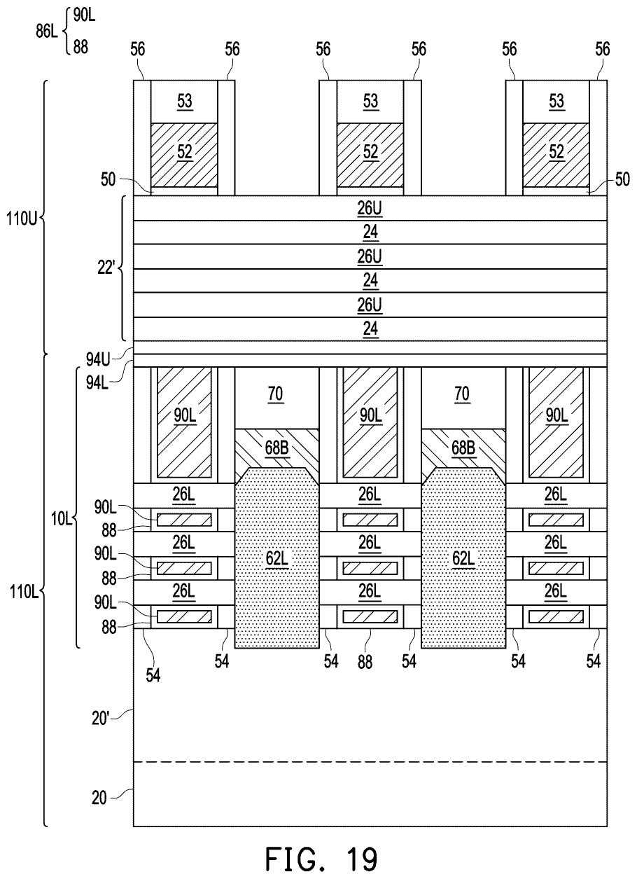

FIGS. 2-18 illustrate cross-sectional views of intermediate stages in the formation of lower wafer 110L and the lower nanostructure-FET 10L in the lower wafer 110L in accordance with some embodiments. FIGS. 19-24 illustrate cross-sectional views of intermediate stages in the formation of upper wafer 110U and the upper nanostructure-FET 10U in the upper wafer 110U in accordance with some embodiments. FIGS. 2-10 illustrate cross-sectional views along a similar cross-section as the vertical reference cross-section B-B′ in FIG. 1. FIGS. 17-19 and 23-24 illustrate cross-sectional views along a similar cross-section as the vertical reference cross-section A-A′ in FIG. 1.

In FIG. 2, wafer 110L, which includes a substrate 20, is provided. The substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. In accordance with some embodiments, the semiconductor material of the substrate 20 may include silicon, germanium, carbon-doped silicon, a III-V compound semiconductor; or the like, or combinations thereof.

A multi-layer stack 22 is formed over the substrate 20. The multi-layer stack 22 includes alternating dummy semiconductor layers 24 and semiconductor layers 26L. The semiconductor layers 26L include lower semiconductor nanostructures 26L. The lower semiconductor nanostructures 26L are for forming a lower FET.

Appropriate well regions (not separately illustrated) such as p-well regions and n-well regions may be formed in lower semiconductor nanostructures 26L. For example, semiconductor nanostructures 26L may be in-situ doped (when epitaxially grown) and/or implanted to desirable conductivity types.

The dummy semiconductor layers 24 are formed of a semiconductor material. The semiconductor material may be selected from the same group of candidate semiconductor materials as the substrate 20.

The lower semiconductor nanostructures 26L are formed of one or more semiconductor material(s). The semiconductor material(s) may also be selected from the same group of candidate semiconductor materials as the substrate 20. The dummy semiconductor layers 24 and the lower semiconductor nanostructures 26L may have a high etching selectivity to one another. As such, the dummy semiconductor layer(s) 24 may be removed at a faster rate than the lower semiconductor nanostructures 26L in subsequent processes.

In accordance with some embodiments, the dummy semiconductor layers 24 are formed of or comprise silicon germanium and the semiconductor layers 26 are formed of silicon.

Multi-layer stack 22 and substrate 20 are patterned to form semiconductor strips 28. Each of the semiconductor strips 28 includes semiconductor strip 20′ (the portions of the original substrate 20) and multi-multi-layer stack 22′, which is the remaining portion of multi-layer stack 22. The layers in the remaining portions 22′ may be referred to as nanostructures hereinafter. The etching may be performed by any acceptable etch process, such as a Reactive Ion Etch (RIE), Neutral Beam Etch (NBE), the like, or a combination thereof. The etching may be anisotropic. The dummy semiconductor layers 24 may further be collectively referred to as dummy nanostructures 24.

The lower semiconductor nanostructures 26L will act as channel regions for lower nanostructure-FETs of the CFETs. The dummy nanostructures 24 will be subsequently replaced with gate structures.

Isolation regions 32 are formed over the substrate 20 and between adjacent semiconductor strips 28. Isolation regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of isolation regions 32 may include depositing the dielectric layer(s), and performing a planarization process such as a Chemical Mechanical Polish (CMP) process, a mechanical polishing process, or the like to remove excess portions of the dielectric materials. The deposition processes may include chemical vapor deposition (CVD), atomic layer deposition (ALD), HDP-CVD, FCVD, the like, or a combination thereof. In accordance with some embodiments, the isolation regions 32 include silicon oxide formed by an FCVD process, followed by an anneal process.

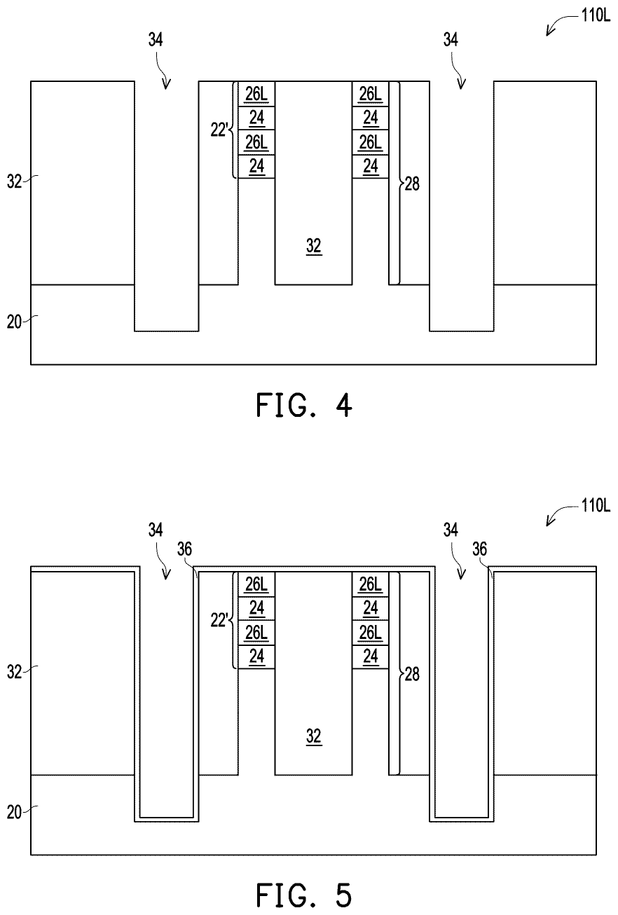

FIGS. 4 through 10 illustrate the formation of buried conductive features, sometimes referred to as buried power rails, in accordance with some embodiments. In FIG. 4, trenches 34 (also referred to as an opening) are formed adjacent to the semiconductor strips 28. The trenches 34 are alternatively referred to as buried power rail trenches. The trenches 34 are formed by etching through the isolation regions 32, as well as the underlying portions of the substrate 20.

To form the trenches 34, a mask (not shown) may be formed and patterned over the structure of FIG. 3. In some embodiments, the mask is a photoresist and may be formed by spin coating or the like and may be exposed to light for patterning. The pattern of the photoresist corresponds to the subsequently formed trenches 34. The patterning forms at least openings through the photoresist to expose the isolations regions 32. In some embodiments, a stop layer (not shown), such as a chemical mechanical polishing (CMP) stop layer is deposited over a top surface of isolations regions 32 before the mask. The CMP stop layer may be used to prevent a subsequent CMP process from removing too much material by being resistant to the subsequent CMP process and/or by providing a detectable stopping point for the subsequent CMP process. In some embodiments, the CMP stop layer may comprise one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, chemical vapor deposition (CVD), plasma-enhanced CVD (PECVD), atomic layer deposition (ALD), the like, or a combination thereof.

In FIG. 4, the patterned mask is used as a mask during an etching process to remove exposed and underlying portions of the isolations regions 32 and the substrate 20. A single etch process may be used to etch trenches 34 in the isolation regions 32 and the substrate 20 or a first etch process may be used to etch isolation regions 32 and a second etch process may be used to etch the substrate 20. In some embodiments, the trenches 34 are formed with a plasma dry etch process, a reactive ion etch (RIE) process, such as a deep RIE (DRIE) process. In some embodiments, the DRIE process includes etch cycle(s) and passivation cycle(s) with the etch cycle(s) using, for example, SF₆, and the passivation cycle(s) using, for example, C₄F₈. The utilization of a DRIE process with the passivation cycle(s) and the etch cycle(s) enables a highly anisotropic etching process. In some embodiments, the etch process(es) may be any acceptable etching process, such as by wet or dry etching.

In FIG. 5, a liner layer 36 is conformally deposited on the isolation regions 32 and on the bottom surface and sidewalls of the trenches 34. In some embodiments, the liner layer 36 includes one or more layers and may be used to physically and electrically isolate the subsequently formed buried conductive feature from the substrate 20. Suitable materials may include oxides (such as silicon oxide, aluminum oxide, or the like), nitrides (such as SiN, or the like), oxynitrides (such as SiON, or the like), combinations thereof, or the like. The liner layer 36 may be formed using CVD, PECVD, ALD, the like, or a combination thereof.

In a subsequent step, a seed layer (not shown) is formed over liner layer 36. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD) or the like. In some embodiments, a barrier layer (not shown) may be formed on the liner layer 36 prior to forming the seed layer. The barrier layer may comprise Ti and TiN, for example.

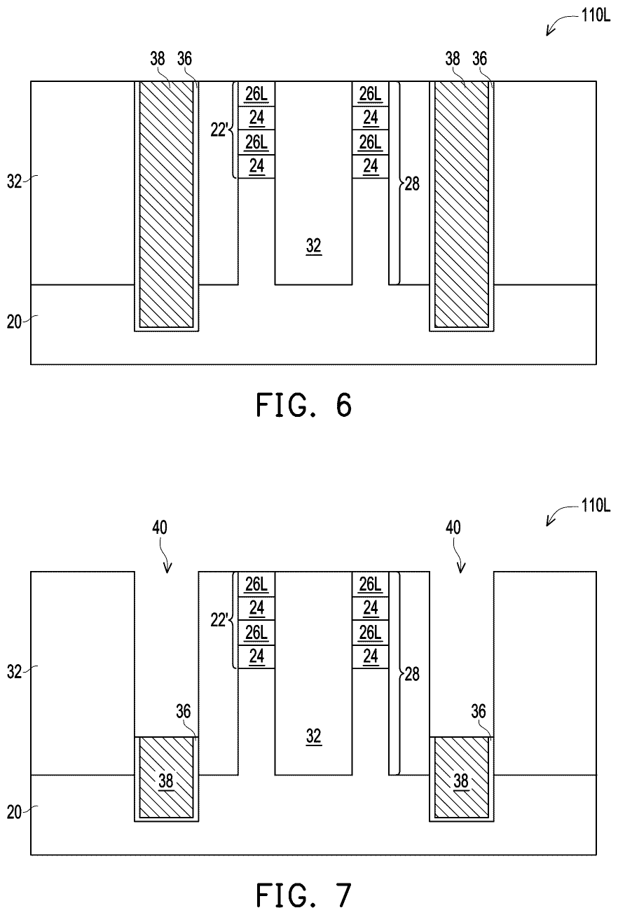

In FIG. 6, a conductive material 38 is formed on the seed layer and fills the trenches 34. The conductive material 38 may be formed by plating, such as electroplating including electrochemical plating, electroless plating, or the like. The conductive material may comprise a metal, like copper, titanium, tungsten, aluminum, or the like.

After the conductive material 38 is formed, a planarization process is performed to remove portions of the conductive material 38, the seed layer, and the liner layer 36 outside the trenches 34 as illustrated in FIG. 6. Top surfaces of the conductive material 38, the liner layer 36, the isolation regions 32, and the semiconductor strips 28 are coplanar after the planarization process within process variations. The planarization process may be, for example, a chemical-mechanical polish (CMP), a grinding process, or the like.

In FIG. 7, the conductive material 38 and the liner layer 36 are recessed to have top surfaces below top surfaces of the isolation regions 32 forming recesses 40 over the recessed conductive material 38 and liner layer 36. In some embodiments, the conductive material 38 and the liner layer 36 are recessed by an etching process. The etching process may be isotropic and may be selective to the material of the conductive material 38 and the liner layer 36, so that the conductive material 38 and the liner layer 36 are etched at a faster rate than the isolation regions 32 and the nanostructures and 26L. In this manner, the conductive material 38 and the liner layer 36 are recessed into the isolation regions 32.

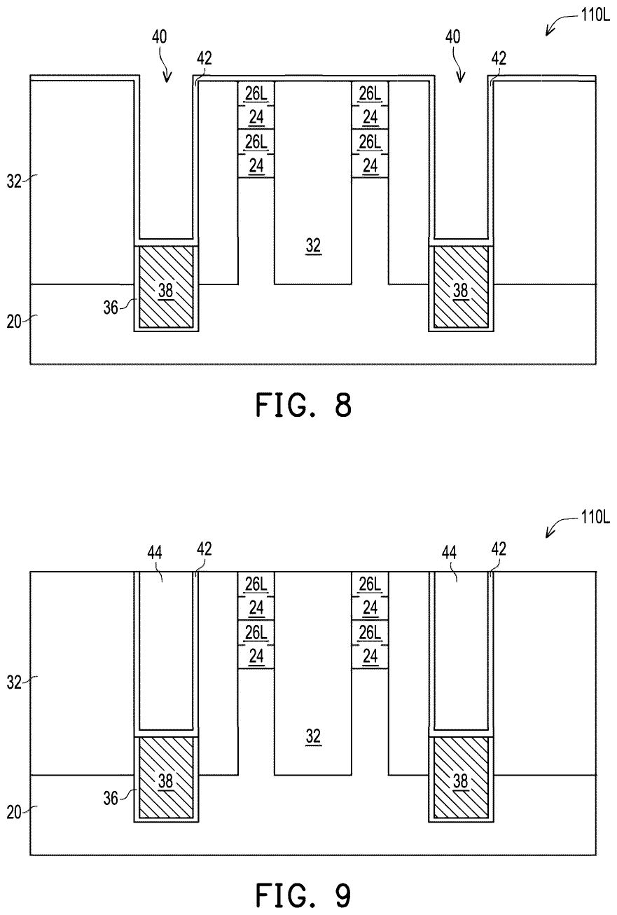

In FIG. 8, a liner layer 42 is conformally deposited on the isolation regions 32 and on the bottom surface and sidewalls of the recesses 40. The liner layer 42 is formed on the isolation regions 32 and top surfaces of the liner layer 36 and conductive material 38 in the recesses 40. In some embodiments, the liner layer 42 includes one or more layers and may include oxides (such as silicon oxide, aluminum oxide, or the like), nitrides (such as SiN, or the like), oxynitrides (such as SiON, or the like), combinations thereof, or the like. The liner layer 42 may be formed using CVD, PECVD, ALD, the like, or a combination thereof. In some embodiments, the liner layer 42 has a same material composition as the liner layer 36, and, in other embodiments, the liner layer 42 has a different material composition than the liner layer 36.

In FIG. 9, a dielectric material 44 is formed in the recesses 40 on the liner layer 42 to fill the recesses 40 over the conductive material 38. The dielectric material 44 may include an oxide such as silicon oxide, a nitride, such as silicon nitride, the like, or a combination thereof. The formation of dielectric material 44 may include depositing the dielectric layer(s), and performing a planarization process such as a CMP process, a mechanical polishing process, or the like to remove excess portions of the dielectric materials. The deposition processes may include CVD, ALD, HDP-CVD, FCVD, the like, or a combination thereof. In some embodiments, dielectric material 44 has a same material composition the isolation regions 32, and, in other embodiments, the dielectric material 44 has a different material composition than the isolations regions 32.

In FIG. 10, isolations regions 32, dielectric material 44, and liner layer 42 are recessed. Some upper portions of semiconductor strips 28 (including multi-layer stacks 22′) protrude higher than the remaining isolations regions 32, dielectric material 44, and liner layer 42 to form protruding fins 33. After the recessing, the top surfaces of the conductive material 38 is still below top surfaces of the isolation regions 32 and dielectric material forming buried conductive features 38.

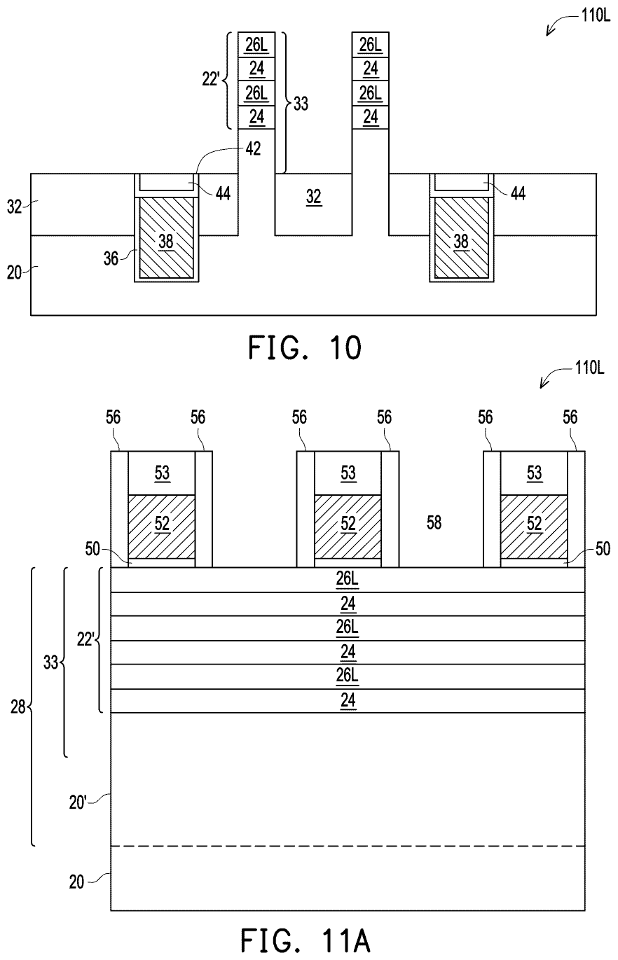

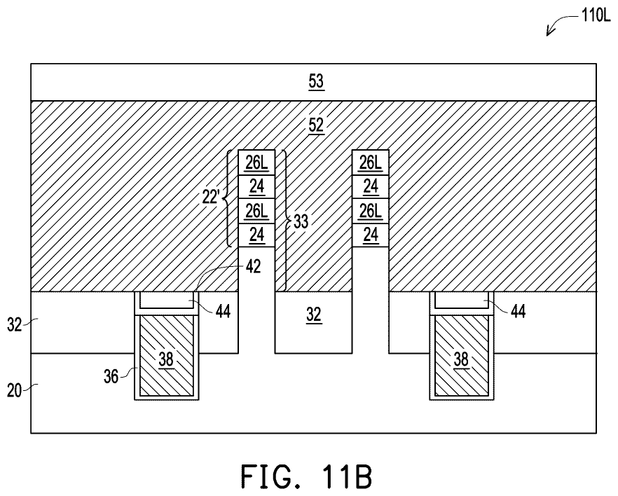

In FIGS. 11A and 11B, dummy gate structures are formed over the fins 33 and the buried conductive features 38. A dummy gate dielectric 50 is formed on the protruding fins 33. The dummy gate dielectric 50 may be formed of or comprise, for example, silicon oxide, silicon nitride, a combination thereof, or the like, and may be deposited or thermally grown according to acceptable techniques. A dummy gate layer 52 is formed over the dummy gate dielectric 50. The dummy gate layer 52 may be deposited, for example, through Physical Vapor Deposition (PVD), CVD, or other techniques, and then planarized, such as by a CMP process. The material of dummy gate layer 52 may be conductive or non-conductive, and may be selected from a group including amorphous silicon, polycrystalline-silicon (polysilicon), poly-crystalline silicon-germanium (poly-SiGe), or the like. One or more mask layer(s) 53 is formed over the planarized dummy gate layer 52, and may include, for example, silicon nitride, silicon oxynitride, or the like.

Next, the mask layer 53 may be patterned through photolithography and etching processes to form a mask, which is then used to etch and pattern dummy gate layer 52, and possibly dummy gate dielectric 50. A resulting structure is shown in FIGS. 11A and 11B. The remaining portions of mask layer 53, dummy gate layer 52, and dummy gate dielectric 50 form dummy gate stacks.

Gate spacers 56 are then formed over the multi-layer stacks 22′ and on the exposed sidewalls of dummy gate stacks. The gate spacers 56 may be formed by conformally depositing one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like.

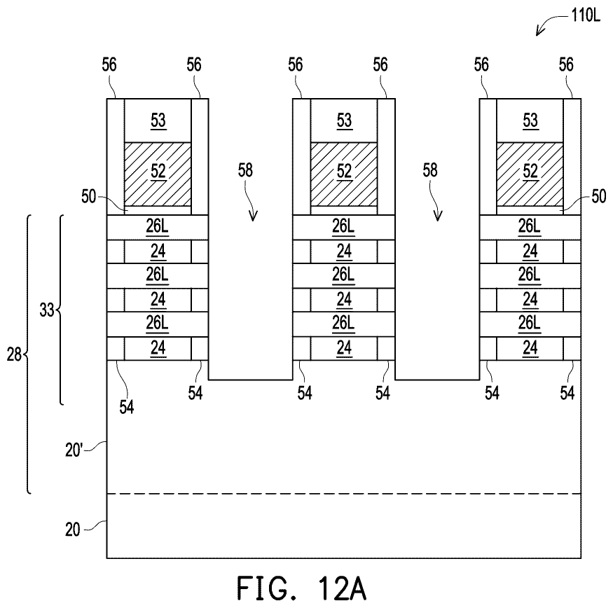

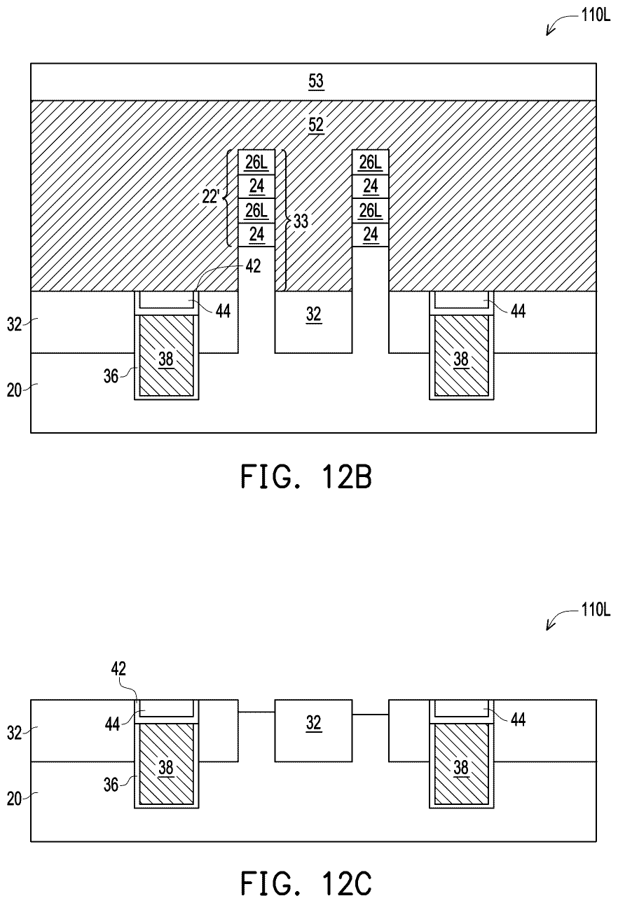

Referring to FIGS. 12A, 12B, and 12C, source/drain recesses 58 are formed in semiconductor strips 28. The source/drain recesses 58 are formed through etching, and may extend through the multi-layer stacks 22′ and into the semiconductor strips 20′. The bottom surfaces of the source/drain recesses 58 may be at a level above, below, or level with the top surfaces of the isolation regions 32. In the etching processes, the gate spacers 56 and the dummy gate stacks mask some portions of the semiconductor strips 28. The etching may include a single etch process or multiple etch processes. Timed etch processes may be used to stop the etching of the source/drain recesses 58 upon source/drain recesses 58 reaching a desired depth. Although not illustrated in FIG. 12C, in some embodiments, gate spacers 12C can extend into the source/drain area.

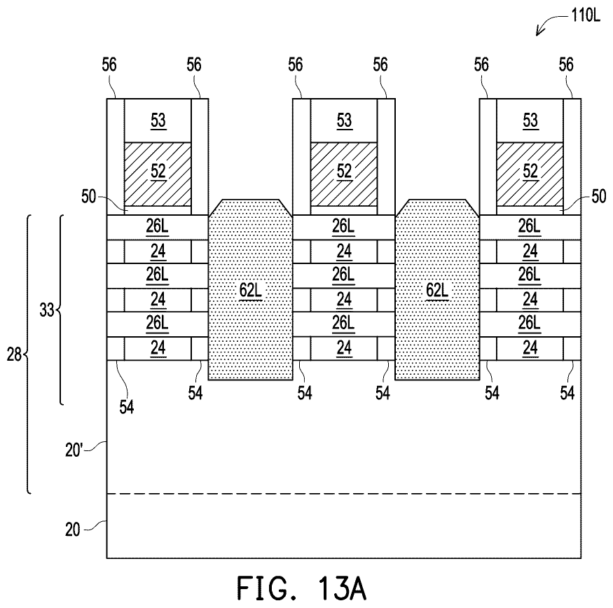

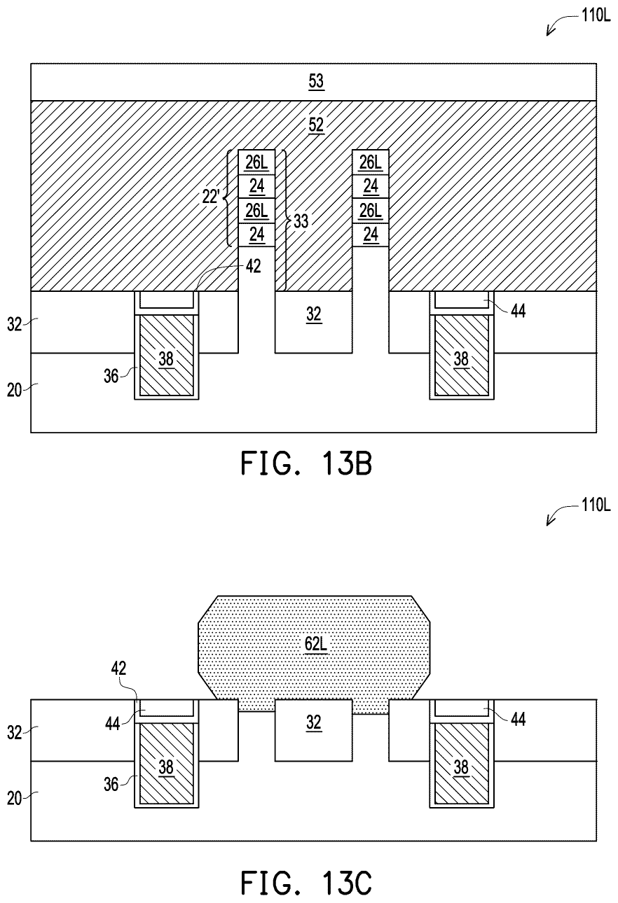

In FIGS. 13A, 13B, and 13C, inner spacers 54 and lower epitaxial source/drain regions 62L are formed. The formation of inner spacers 54 may include an etching process that laterally etches the dummy semiconductor layers 24. The etching process may be isotropic and may be selective to the material of the dummy semiconductor layers 24, so that the dummy semiconductor layers 24 are etched at a faster rate than the lower semiconductor nanostructures 26L. In this manner, the dummy semiconductor layers 24 are laterally recessed.

In some embodiments, the dummy semiconductor layers 24 are formed of silicon germanium, and the lower semiconductor nanostructures 26L are formed of silicon free from germanium, the etch process may comprise a dry etch process using chlorine gas, with or without a plasma. Further, although the sidewalls of the dummy semiconductor layers 24 are illustrated as being straight after the etching, the sidewalls may be concave or convex.

Inner spacers 54 are formed on sidewalls of the laterally recessed dummy semiconductor layers 24. In the subsequent formation of source/drain regions, the inner spacers 54 may act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures.

The inner spacers 54 may be formed by conformally depositing a dielectric insulating material in the source/drain recesses 58, and then etching the insulating material. The insulating material may be a non-low-k dielectric material, which may be a carbon-containing dielectric material such as silicon oxycarbonitride, silicon oxycarbide, silicon oxynitride, or the like. The insulating material may be formed by a deposition process, such as ALD, CVD, or the like. The etching of the insulating material may be anisotropic or isotropic. The insulating material, after being etched, has portions remaining on the sidewalls of the dummy semiconductor layers 24 (thus forming the inner spacers 54).

Further in FIGS. 13A, 13B, and 13C, lower epitaxial source/drain regions 62L are formed. The lower epitaxial source/drain regions 62L are formed in the source/drain recesses 58. The lower epitaxial source/drain regions 62L are in contact with the lower semiconductor nanostructures 26L. Inner spacers 54 electrically insulate the lower epitaxial source/drain regions 62L from the dummy semiconductor layers 24, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

As a result of the epitaxy processes used to form the lower source/drain regions 62L, upper surfaces of the lower source/drain regions 62L have facets which expand laterally outward beyond sidewalls of the nanostructures 26L. In some embodiments, these facets cause adjacent lower source/drain regions 62L of a same nanostructure-FET to merge as illustrated by FIG. 13C. In other embodiments, adjacent lower source/drain regions 62L remain separated after the epitaxy process is completed (not separately illustrated). In the illustrated embodiments, there are no gate spacers formed on a top surface of the isolation regions 32 (maybe referred to as fin spacers) in the source/drain area and can block lateral epitaxial growth. In the illustrated embodiment, the spacer etch used to form the gate spacers 56 is adjusted to not form the fin spacers, so as to allow the lower source/drain regions 62L to extend to the surface of the isolation regions 32.

In some embodiments, a Contact Etch Stop Layer (CESL) (not shown) is formed over the lower epitaxial source/drain regions 62L. The CESL may be formed of a dielectric material having a high etching selectivity from the etching of subsequent ILD, such as silicon nitride, silicon oxide, silicon oxynitride, or the like, which may be formed by any suitable deposition process, such as CVD, ALD, or the like.

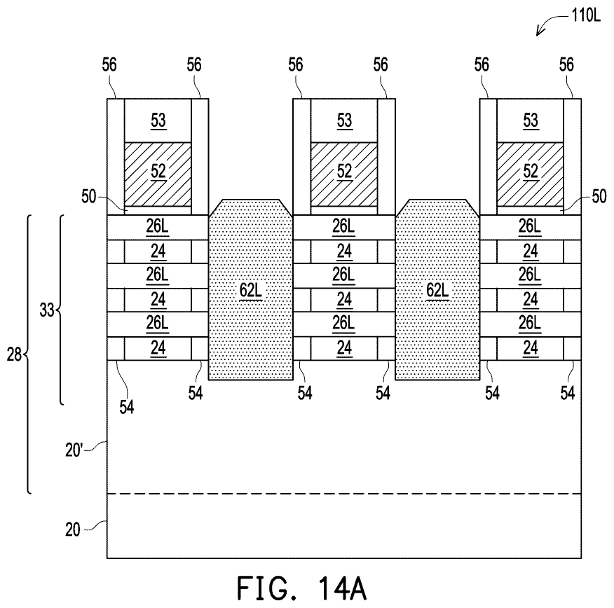

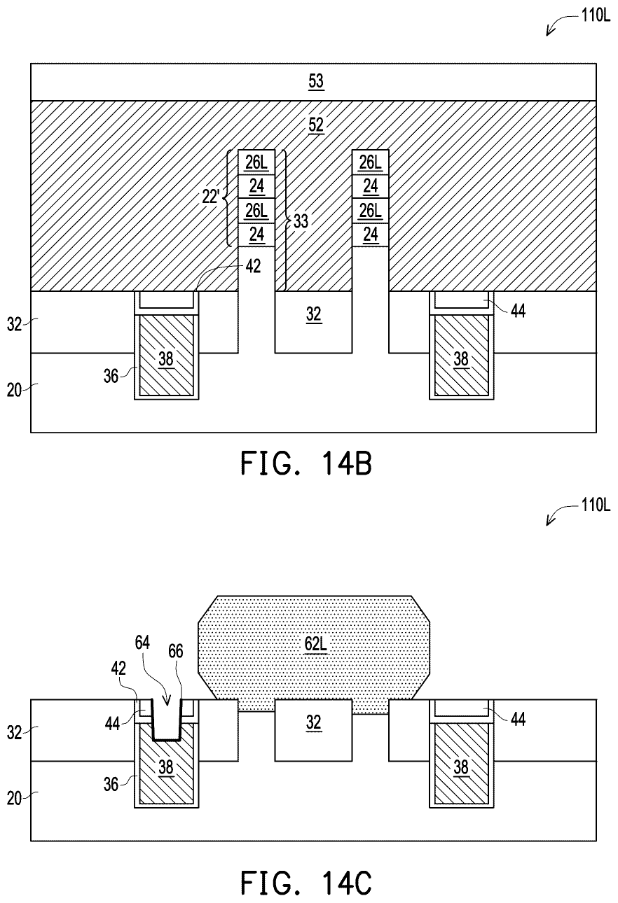

In FIGS. 14A, 14B, and 14C, an opening 64 is formed through the dielectric material 44 and the liner layer 42 to one of the buried conductive features 38. In some embodiments, one of the buried conductive feature 38 is connected to a power supply node V_{DD} and the other buried conductive feature 38 is connected to a bit line node or low voltage (e.g., Vₛₛ) voltage node. For example, the left buried conductive feature 38 in FIG. 14C is V_{DD} and the right buried conductive feature is a bit line.

In FIG. 14C the opening 64 (may also be referred to as via 64) is formed adjacent to the lower epitaxial source/drain regions 62L. The opening 64 are formed by etching through the dielectric material 44 and the liner layer 42, as well as the underlying portions of the conductive material 38.

In some embodiments, the opening 64 is formed to a depth in a range from 10 nm to 50 μm, such as, for example, 30 nm or 500 nm.

To form the opening 64, a mask (not shown) may formed and patterned over the structure of FIG. 13C. In some embodiments, the mask is a photoresist and may be formed by spin coating or the like and may be exposed to light for patterning. The pattern of the photoresist corresponds to the subsequently formed opening 64. The patterning forms at least openings through the photoresist to expose the dielectric material 44.

In FIG. 14C, the patterned mask is used as a mask during an etching process to remove exposed and underlying portions of the dielectric material 44, the liner layer 42, and the buried conductive feature 38. A single etch process may be used to etch openings 64 the dielectric material 44, the liner layer 42, and the buried conductive feature 38 or a first etch process may be used to etch the dielectric material 44, a second etch process may be used to etch the liner layer 42, and a third etch process may be used to etch the buried conductive feature 38. In some embodiments, the openings 64 are formed with a plasma dry etch process, a RIE process, such as a DRIE process. In some embodiments, the etch process(es) may any acceptable etching process, such as by wet or dry etching. In some embodiments, the etching process is a laser etch process.

Further in FIG. 14C, a liner layer 66 is conformally deposited on the dielectric material 44 and on the bottom surface and sidewalls of the openings 64. In some embodiments, the liner layer 66 includes one or more layers. Suitable materials may include oxides (such as silicon oxide, aluminum oxide, or the like), nitrides (such as SiN, or the like), oxynitrides (such as SiON, or the like), combinations thereof, or the like. The liner layer 66 may be formed using CVD, PECVD, ALD, the like, or a combination thereof.

In a subsequent step, a seed layer (not shown) is formed over liner layer 66. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. In some embodiments, a barrier layer (not shown) may be formed on the liner layer 66 prior to forming the seed layer. The barrier layer may comprise Ti and TiN, for example.

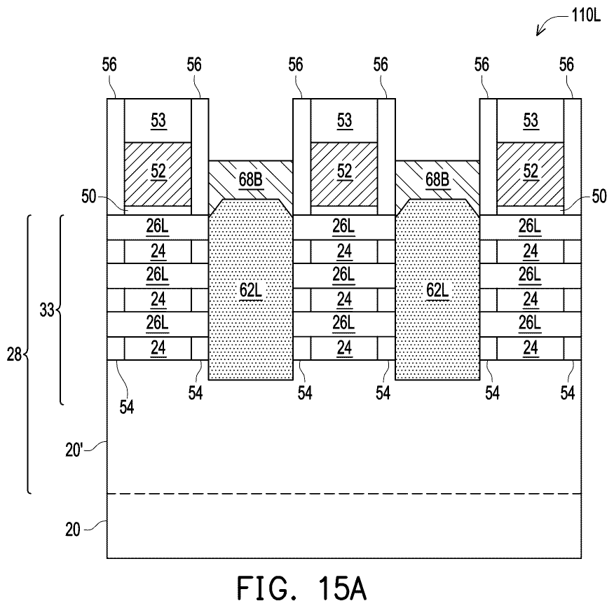

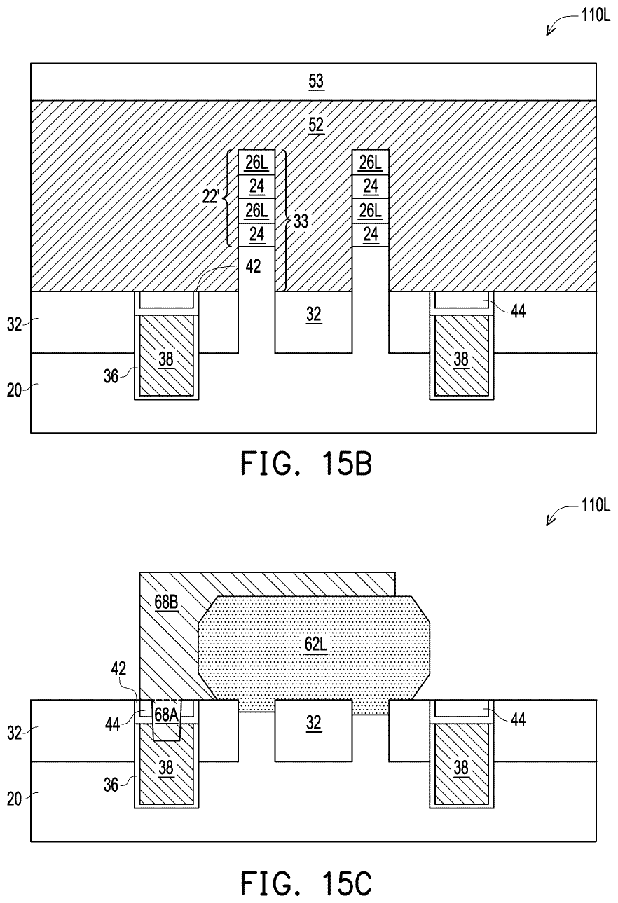

In FIGS. 15A, 15B, and 15C, a conductive material 68 is formed on the seed layer and fills the opening 64 and extends on a sidewall and a top surface of the lower source/drain region 62L (see, e.g., FIGS. 15A and 15C). The conductive material 68 forms a contact 68B and a via 68A. The via 68A is below the top surface of the dielectric material 44. The contact 68B may be referred to as a butted contact 68B. The contact 68B and via 68A connect the buried conductive feature (e.g., V_{DD}) and the lower source/drain region 62L together. As illustrated, the contact 68B extends along and covers one sidewall and extends across along most of the top surface of the lower source/drain region 62L. In some embodiments, the contact 68B extends along and covers both sidewalls and extends across the entire the top surface of the lower source/drain region 62L in the cross-sectional view of FIG. 15C.

In some embodiments, a mask (not shown) may formed and patterned over the structure of FIG. 14C. In some embodiments, the mask is a photoresist and may be formed by spin coating or the like and may be exposed to light for patterning. The pattern of the photoresist corresponds to the subsequently formed contact 68B. The conductive material 68 may be formed by plating, such as electroplating including electrochemical plating, electroless plating, or the like. The conductive material may comprise a metal, like copper, titanium, tantalum, tungsten, aluminum, nickel, cobalt, hafnium, ruthenium, zirconium, zinc, iron, tin, silver, molybdenum, chromium, the like, or compounds thereof.

After the conductive material 68 is formed, a planarization process may be performed to remove upper portions of the conductive material 68. The planarization process may be, for example, a CMP, a grinding process, or the like. The planarization process may be omitted.

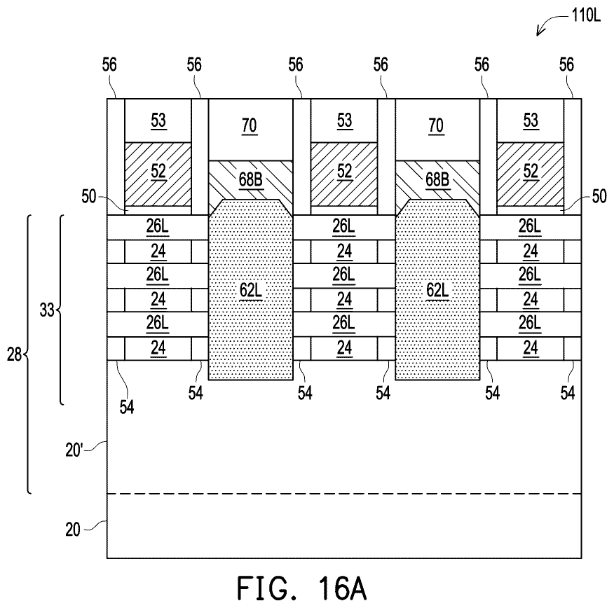

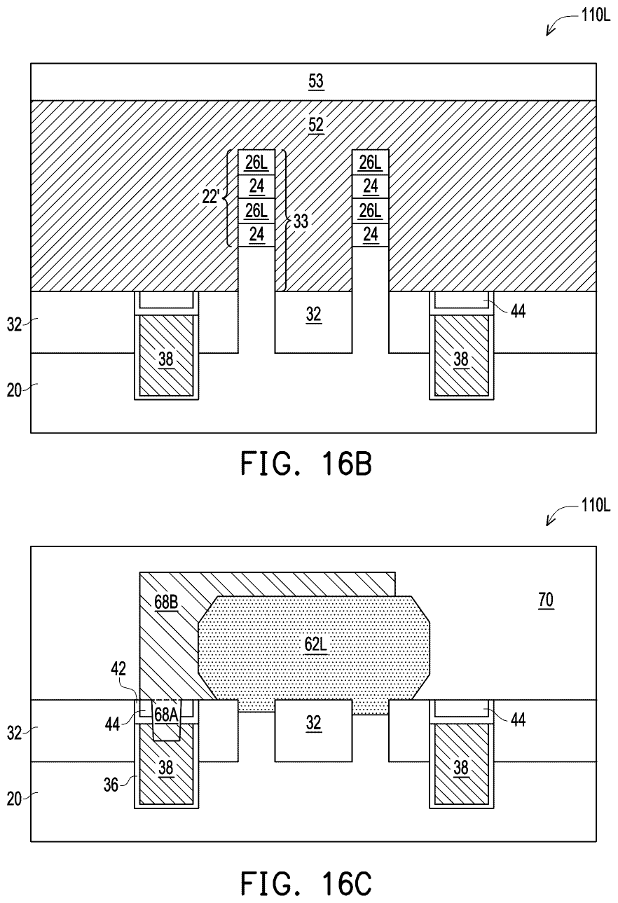

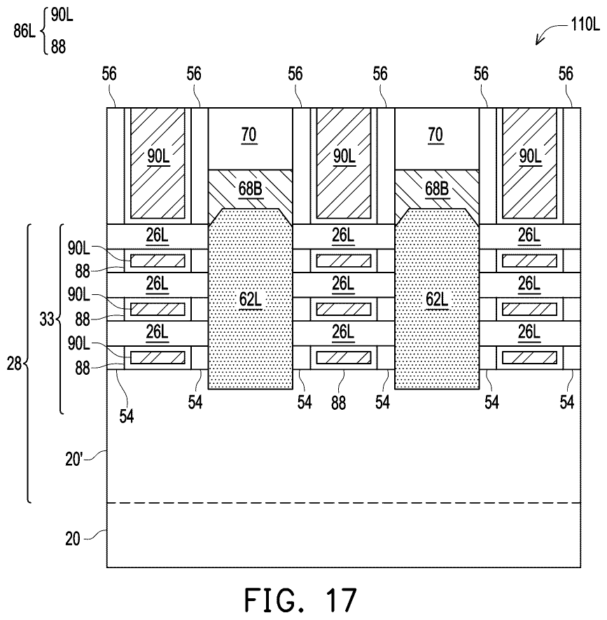

In FIGS. 16A, 16B, and 16C, an interlayer dielectric (ILD) 70 is formed in the between the gate structures and over the contacts 68B and the lower source/drain region 62L. The ILD 70 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a CESL (not shown) is formed between the ILD 70 and the contacts 68B and the lower epitaxial source/drain regions 62L. The CESL may be formed of a dielectric material having a high etching selectivity from the etching of the first ILD 70, such as silicon nitride, silicon oxide, silicon oxynitride, or the like, which may be formed by any suitable deposition process, such as CVD, ALD, or the like.

After the ILD 70 is formed, a planarization process is performed to remove portions of the ILD 70 above the dummy gate stacks. The planarization process may be, for example, a CMP, an etching process, or the like.

In FIG. 17, the dummy gate stacks are removed and replaced with replacement gate stacks 86. In some embodiments, the dummy gate stacks are removed in one or more etching steps, so that recesses are formed between the gate spacers 56, and extend to a level lower than multi-layer stacks 22′. The sidewalls of multi-layer stacks 22′ are thus exposed, and the sidewalls of lower nanostructures 26L and dummy semiconductor layers 24 are exposed.

Dummy semiconductor layers 24 are then removed, so that the recesses extend laterally between lower semiconductor nanostructures 26L. In accordance with some embodiments, the dummy gate stacks and the dummy gate dielectrics 50 are removed by isotropic etching processes. Dummy semiconductor layers 24 can be removed by any acceptable etch process that selectively etches the material of the dummy semiconductor layers 24 at a faster rate than the materials of the lower semiconductor nanostructures 26L and the inner spacers 54. The etching may be isotropic.

Further in FIG. 17, replacement gate stacks 86L are formed, which include gate dielectrics 88 and gate electrodes 90L. Gate dielectrics 88 may be conformally formed on the channel regions of the lower semiconductor nanostructures 26L. Each of the gate dielectrics 88 may include an interfacial layer (IL), which may be formed of or comprises an oxide such as silicon oxide or a metal oxide, a silicate such as a metal silicate, combinations thereof, multi-layers thereof, or the like. Each of the gate dielectrics 88 may also include a high dielectric constant (high-k) dielectric layer formed of a high-k dielectric material having a k-value greater than 3.9, and possibly greater than about 7.0. The high-k dielectric material may comprise a metal oxide or a metal nitride of metals such as hafnium, aluminum, zirconium, lanthanum, manganese, barium, titanium, lead. The formation methods of the gate dielectrics 88 may include molecular-beam deposition (MBD), ALD, PECVD, and the like.

Further referring to FIG. 17, lower gate electrodes 90L are formed on the gate dielectrics 88. The lower gate electrodes 90L are disposed between the lower semiconductor nanostructures 26L. Accordingly, the lower gate electrodes 90L also wrap around the lower semiconductor nanostructures 26L.

Lower gate electrodes 90L may include adhesion layers, work-function layers, a filling metal, or the like. The materials of the work-function layers are selected based on the conductivity type of the respective FET. For example, for an n-type FET, n-type work function materials such as TiAl, TiAlN, or the like may be used to form the work-function layer. For a p-type FET, p-type work function materials such as TiN may be used to form the work-function layer. In accordance with some embodiments, the upper gate electrodes 90U may be recessed to form recesses between opposing gate spacers 56, followed by filling a dielectric material into the recesses to form gate hard masks (not shown).

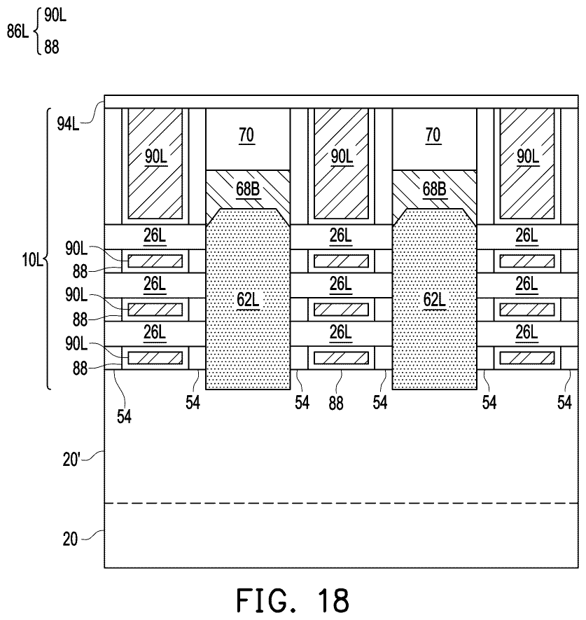

In FIG. 18, a bond layer 94L is formed. In accordance with some embodiments, bond layer 94L is formed through a deposition process such as CVD, ALD, PECVD, or the like. A planarization process may be performed to level the top surface of the bond layer 94L. The bond layer 94L may be formed of or comprise a silicon-containing dielectric material such as silicon oxide, silicon nitride, silicon oxynitride, silicon oxycarbide, silicon oxycarbonitride, or the like.

Next, as shown in FIG. 19, multi-layer stack 22′ are formed, and are bonded to the underlying lower wafer 110L through a bond layer 94U. The bond layer 94U may also be formed of or comprise a silicon-containing dielectric material such as silicon oxide, silicon nitride, silicon oxynitride, silicon oxycarbide, silicon oxy carbonitride, or the like.

The multi-layer stack 22′ as shown in FIG. 19 may be essentially the same as the multi-layer stack 22′ as shown in FIG. 11A. The formation process of the structure as shown in FIG. 19 may thus be essentially the same as discussed referring to FIGS. 2 and 11A. Also, there may be a plurality of strips of multi-layer stack 22′ (similar to what is illustrated in FIG. 2) parallel to, and close to, each other. The top layer in multi-layer stack 22′ may be a semiconductor nanostructures 26U, which may be formed of silicon. The bottom layer in multi-layer stack 22′ may be a dummy semiconductor layers 24, which may be formed of silicon germanium.

In accordance with some embodiments, the formation and the bonding of bond layer 94U and the multi-layer stack 22′ may include forming alternating layers of semiconductor nanostructures 26U and dummy semiconductor layers 24 on a semiconductor substrate, and depositing a bond layer 94U on the multi-layer stack 22′. The alternating layers of semiconductor nanostructures 26U and dummy semiconductor layers 24 are epitaxially grown in a plurality of epitaxy processes, each forming one of semiconductor nanostructures 26U and dummy semiconductor layers 24. The resulting structure is thus referred to as upper wafer 110U. The upper wafer 110U is then bonded to lower wafer 110L through the bonding of bond layer 94U to bond layer 94L.

In accordance with alternative embodiments, instead of pre-forming upper wafer 110U and bonding upper wafer 110U to lower wafer 110L, the bond layer 94U is first formed on a semiconductor layer (not shown), which may be a silicon germanium layer. The bond layer 94U is then bonded to bond layer 94L in the lower wafer 110L along with the overlying semiconductor layer. The semiconductor layer is then thinned to a desirable thickness to form the bottom dummy semiconductor layer 24. Alternating layers of semiconductor nanostructures 26U and dummy semiconductor layers 24 are then epitaxially grown on the bottom dummy semiconductor layer 24.

Further referring to FIG. 19, a plurality of dummy gate stacks are formed, each comprising a dummy gate dielectric 50, a dummy gate electrode 52, and possibly one or more mask layer 53. The plurality of dummy gate stacks are also formed as a plurality of strips having lengthwise directions perpendicular to the lengthwise directions of multi-layer stack 22′. Also, the plurality of dummy gate stacks extend on the top surfaces (as shown in FIG. 19) and on the sidewalls of multi-layer stack 22′. Gate spacers 56 are then formed on the sidewalls of dummy gate stacks.

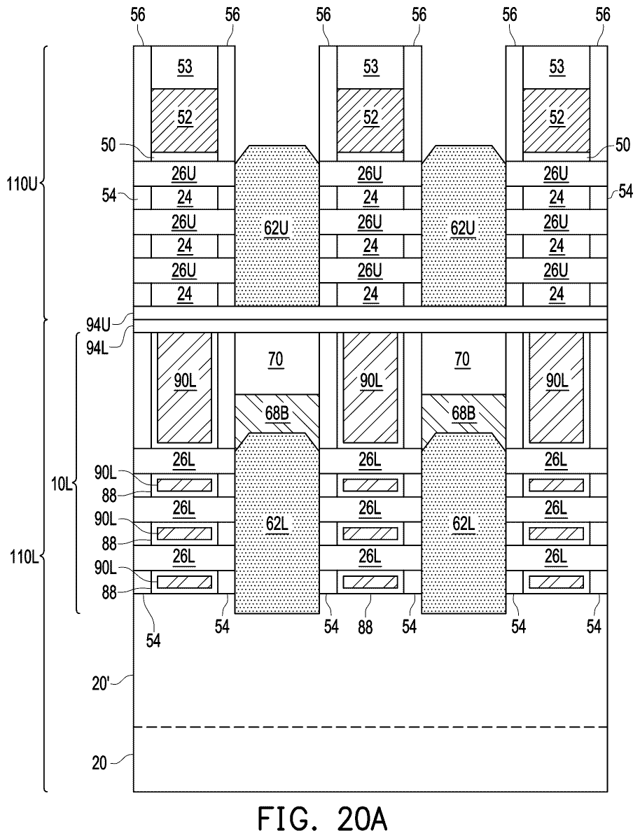

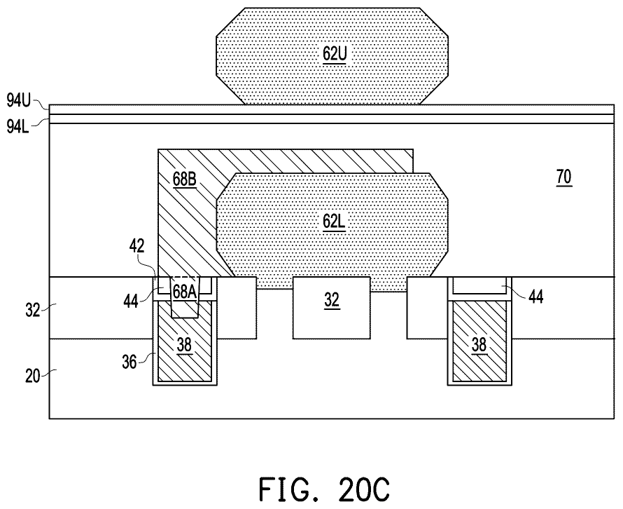

Next, as shown in FIGS. 20A and 20C, inner spacers 54 and source/drain regions 62U are formed. The formation process may include anisotropically etching multi-layer stack 22′ to from openings (also referred to as source/drain recesses), until bond layer 94U is exposed. Inner spacers 54 are then formed by laterally recessing dummy semiconductor layers 24 to form lateral recesses, and filling a dielectric material in the lateral recesses. Source/drain regions 62U are then formed. It is appreciated that some details of a plurality of processes may be the same as or may be realized from the discussion of FIGS. 2 through 18, and hence these details may not be discussed herein.

In FIGS. 20A and 20C, upper epitaxial source/drain regions 62U are formed. The upper epitaxial source/drain regions 62U are formed in the source/drain recesses. The upper epitaxial source/drain regions 62U are in contact with the upper semiconductor nanostructures 26U and the bond layer 94U. Inner spacers 54 electrically insulate the upper epitaxial source/drain regions 62U from the dummy semiconductor layers 24, which will be replaced with replacement gates in subsequent processes.

The upper epitaxial source/drain regions 62U are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

As a result of the epitaxy processes used to form the upper epitaxial source/drain regions 62U, upper surfaces of the upper epitaxial source/drain regions 62U have facets which expand laterally outward beyond sidewalls of the upper nanostructures 26U. In some embodiments, these facets cause adjacent upper epitaxial source/drain regions 62U of a same nanostructure-FET to merge as illustrated by FIG. 20C. In other embodiments, adjacent upper epitaxial source/drain regions 62U remain separated after the epitaxy process is completed (not separately illustrated). In the illustrated embodiments, there are no gate spacers formed on a top surface of the bonding layer 94U (maybe referred to as fin spacers) in the source/drain area and can block lateral epitaxial growth. In the illustrated embodiment, the spacer etch used to form the gate spacers 56 is adjusted to not form the fin spacers, so as to allow the upper epitaxial source/drain regions 62U to extend to the surface of the bond layer 24U.

The conductivity type of the upper epitaxial source/drain regions 62U may be opposite the conductivity type of the lower epitaxial source/drain regions 62L. For example, the upper epitaxial source/drain regions 62U may be oppositely doped than the lower epitaxial source/drain regions 62L.

In some embodiments, a CESL (not shown) is formed over the upper epitaxial source/drain regions 62U. The CESL may be formed of a dielectric material having a high etching selectivity from the etching of subsequent ILD, such as silicon nitride, silicon oxide, silicon oxynitride, or the like, which may be formed by any suitable deposition process, such as CVD, ALD, or the like.

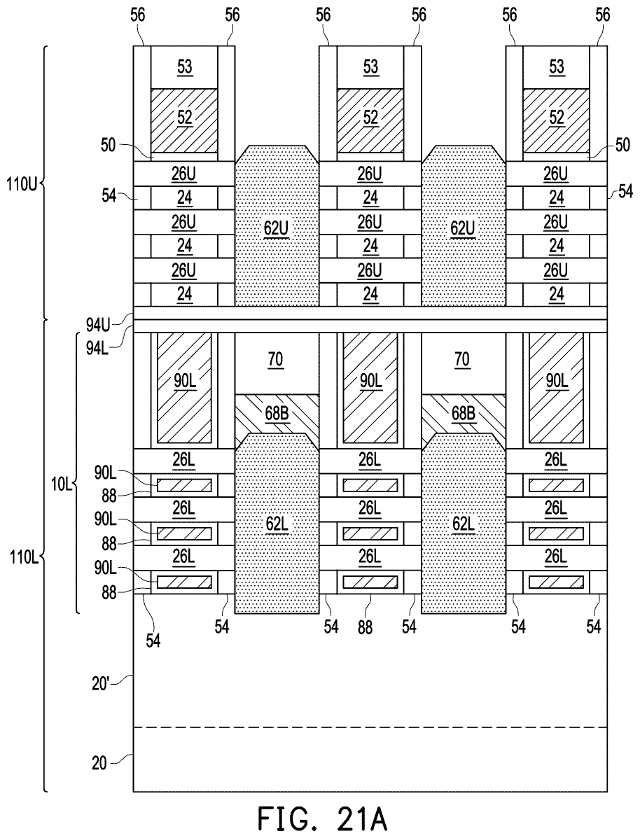

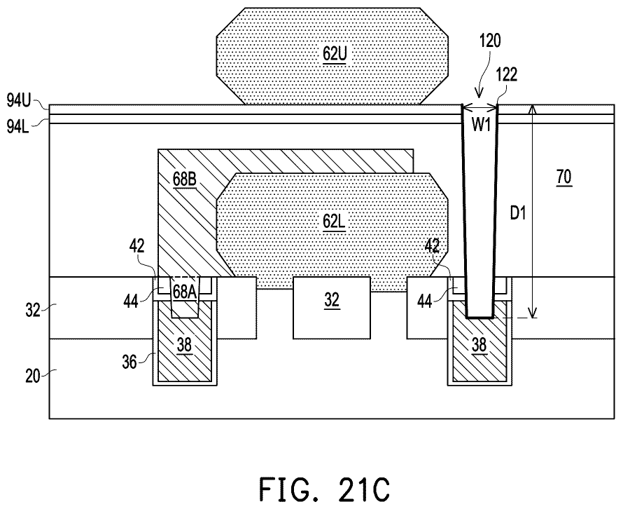

In FIGS. 21A and 21C, an opening 120 is formed through the bonding layers 94U and 94L, the ILD 70, the dielectric material 44, and the liner layer 42 to one of the buried conductive features 38. In some embodiments, one of the buried conductive feature 38 is connected to a power supply node V_{DD} and the other buried conductive feature 38 is connected to a bit line node. For example, the left buried conductive feature 38 in FIG. 14C is VDD and the right buried conductive feature is a bit line.

The opening 120 is formed to a depth D1. In some embodiments, the depth D1 is in a range from 10 nm to 50 μm, such as for example, 300 nm or 1 μm. The opening 120 cannot be too short or too long. If, for example, the opening 120 is too short, the subsequently formed via fuse in the opening 120 may not be able to operably function as a fuse.

The opening 120 is formed to have a width W1 at the top of the opening 120 adjacent the bonding layers 94. In some embodiments, the width W1 is in a range from 5 nm to 100 nm, such as for example, 10 nm or 20 nm. In some embodiments, the opening 120 is a square or circle in a plan view with the top surface of having an area substantially the size of W1×W1. The opening 120 cannot be too wide or too narrow. If, for example, the opening 120 is too wide, the subsequently formed via fuse in the opening 120 may not be able to operably function as a fuse.

In FIG. 21C the opening 120 (may also be referred to as via 120) is formed adjacent to the upper epitaxial source/drain regions 62U. The opening 120 is formed by etching through the bonding layers 94U and 94L, the ILD 70, the dielectric material 44, and the liner layer 42, as well as into the underlying portions of the conductive material 38. In some embodiments, the

To form the opening 120, a mask (not shown) may be formed and patterned over the structure of FIG. 20C. In some embodiments, the mask is a photoresist and may be formed by spin coating or the like and may be exposed to light for patterning. The pattern of the photoresist corresponds to the subsequently formed opening 120. The patterning forms at least openings through the photoresist to expose the bonding layer 94U.

In FIG. 21C, the patterned mask is used as a mask during an etching process to remove exposed and underlying portions of the bonding layers 94U and 94L, the ILD 70, the dielectric material 44, and the liner layer 42, and the buried conductive feature 38. A single etch process may be used to etch openings 120 into the dielectric material 44, the liner layer 42, and the buried conductive feature 38 or a first etch process may be used to etch the bonding layers 94U and 94L, a second etching process may be used to etch ILD 70, a third etching process may be used to etch dielectric material 44, a fifth etch process may be used to etch the liner layer 42, and a sixth etch process may be used to etch the buried conductive feature 38. In some embodiments, the opening 230 is formed with a plasma dry etch process, a RIE process, such as a DRIE process. In some embodiments, the etch process(es) may any acceptable etching process, such as by wet or dry etching. In some embodiments, the etching process is a laser etch process.

Further in FIG. 21C, a liner layer 122 is conformally deposited on the bonding layers 94U and 94L and on the bottom surface and sidewalls of the opening 120. In some embodiments, the liner layer 122 includes one or more layers. Suitable materials may include oxides (such as silicon oxide, aluminum oxide, or the like), nitrides (such as SiN, or the like), oxynitrides (such as SiON, or the like), combinations thereof, or the like. The liner layer 122 may be formed using CVD, PECVD, ALD, the like, or a combination thereof.

In a subsequent step, a seed layer (not shown) is formed over liner layer 122. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. In some embodiments, a barrier layer (not shown) may be formed on the liner layer 122 prior to forming the seed layer. The barrier layer may comprise Ti and TiN, for example.

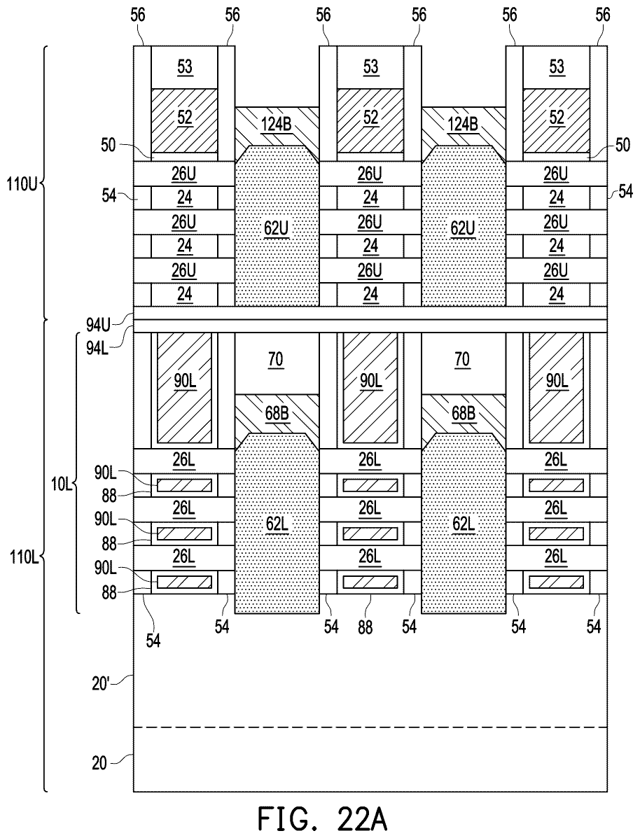

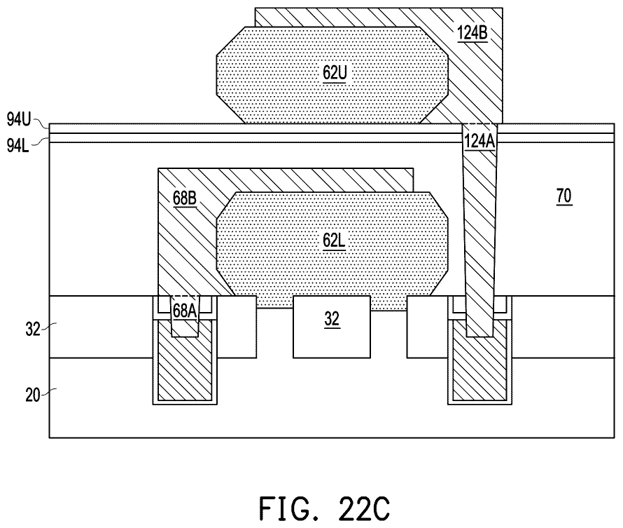

In FIGS. 22A and 22C, a conductive material 124 is formed on the seed layer and fills the opening 120 and extends on a sidewall and a top surface of the upper source/drain region 62U (see, e.g., FIGS. 22A and 22C). The conductive material 124 forms a via fuse 124A and a contact 124B. The via fuse 124A is the portion below the bonding layers 94 and the contact is above the bonding layers 94 although the two portions may be formed by a continuous process and comprise a continuous material. In some embodiments, the via fuse 124A is longer than the via 68A. The via fuse 124A and the contact 124B connects the buried conductive feature (e.g., a bit line) and the upper source/drain region 62U together. As illustrated, the contact 124B extends along and covers one sidewall and extends across along most of the top surface of the upper source/drain region 62U. In some embodiments, the contact 124B extends along and covers both sidewalls and extends across the entire the top surface of the upper source/drain region 62U in the cross-sectional view of FIG. 22C.

The via fuse 124A may subsequently be used as a fuse to remove a devices from the active circuitry. For example, it may be later determined (e.g., from testing of the semiconductor device) that some of the devices connected to upper transistor 10U are faulty and should be removed from the active circuitry. In some embodiments, a high voltage stress followed by a high current flows through the via fuse 124A causing electromigration in the via fuse 124A forming an opening in the via fuse 124A. This process of forming the opening in the via fuse 124A through electromigration may be referred to as eFuse programming. Before programming, the resistance of the via fuse 124A is in a low resistance state and can be measured when reading the corresponding memory cell. After programming the via fuse 124A is in a high resistance state which can be measured when reading the corresponding memory cell. In some embodiments, the resistance state of the via fuse 124A is determined by the read current that flows through the via fuse 124A (e.g., a high read current before programming, and a small read current after programming).

In some embodiments, a mask (not shown) may be formed and patterned over the structure of FIG. 21C. In some embodiments, the mask is a photoresist and may be formed by spin coating or the like and may be exposed to light for patterning. The pattern of the photoresist corresponds to the subsequently formed contact 124. The conductive material 124 may be formed by plating, such as electroplating including electrochemical plating, electroless plating, or the like. The conductive material may comprise a metal, like copper, titanium, tantalum, tungsten, aluminum, nickel, cobalt, hafnium, ruthenium, zirconium, zinc, iron, tin, silver, molybdenum, chromium, the like, or compounds thereof.

After the conductive material 124 is formed, a planarization process may be performed to remove upper portions of the contact 124B. The planarization process may be, for example, a CMP, a grinding process, or the like. The planarization process may be omitted.

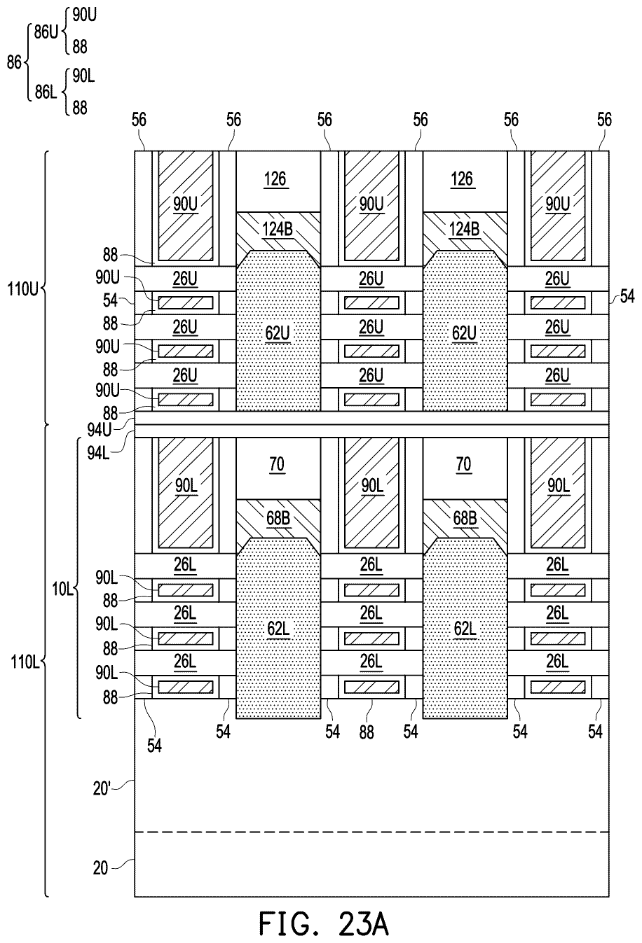

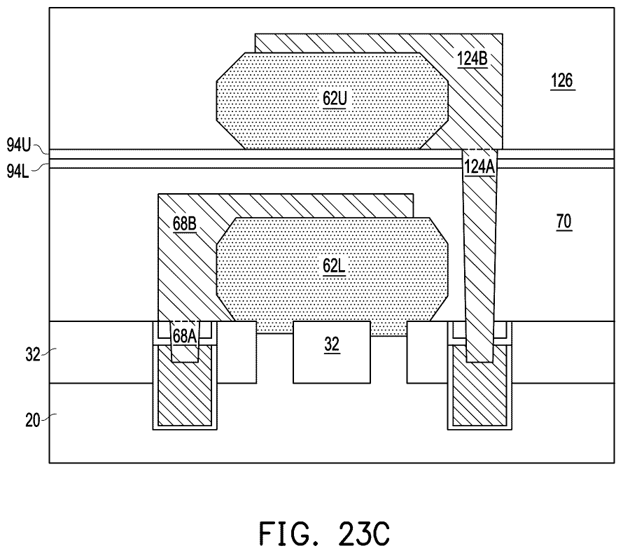

In FIGS. 23A and 23C, an ILD 236 is formed in the between the gate structures and over the contacts 124 and the upper source/drain region 62U. The ILD 126 may be formed of a dielectric material, which may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a CESL (not shown) is formed between the ILD 126 and the contacts 124 and the upper epitaxial source/drain regions 62U. The CESL may be formed of a dielectric material having a high etching selectivity from the etching of the ILD 126, such as silicon nitride, silicon oxide, silicon oxynitride, or the like, which may be formed by any suitable deposition process, such as CVD, ALD, or the like.

After the ILD 126 is formed, a planarization process is performed to remove portions of the ILD 126 above the gate stacks. The planarization process may be, for example, a CMP, an etching process, or the like.

Further in FIGS. 23A and 23C, the dummy gate stacks as shown in FIG. 22A are removed, and replacement gate stacks 86U are formed, and extend to the spaces between neighboring semiconductor nanostructures 26U. The formation of gate stacks 86U are not discussed in detail herein, and may be found from the discussions of the preceding embodiments. Upper transistor 10U is thus formed. The lower nanostructure FETs 10L and upper nanostructure FETs 10U collectively form CFET 10. Throughout the description, the features higher than bond layer 94L are collectively referred to as upper wafer 110U.

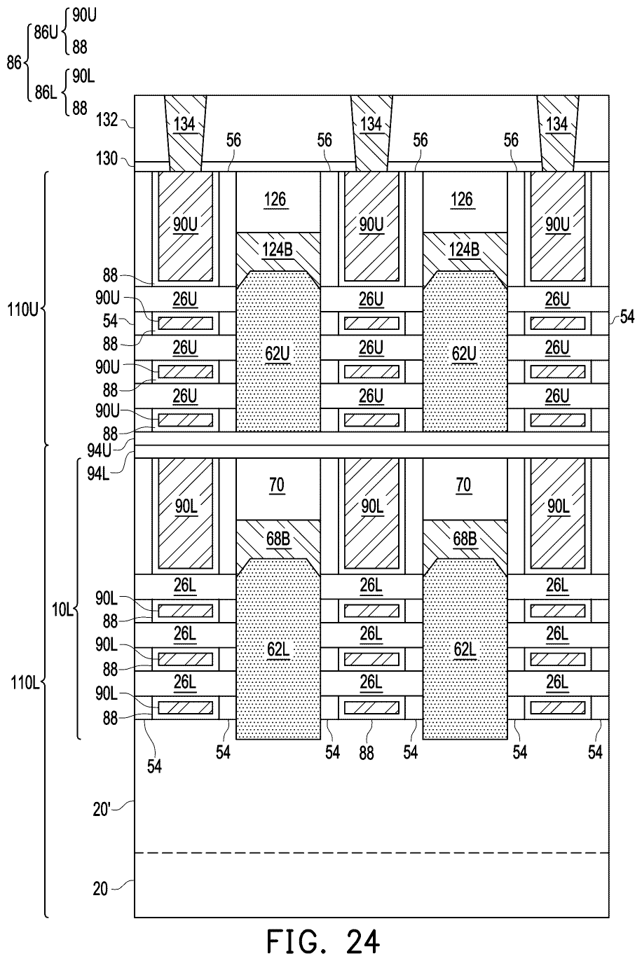

Referring to FIG. 24, gate contact plugs 134 are formed to electrically coupling to gate electrodes 90U. Etch stop layer 130 and ILD 132 are also formed. The top surfaces of gate contact plugs 134 and ILD 132 may be made coplanar through a planarization process such as a CMP process or a mechanical grinding process in accordance with some embodiments.

In embodiments with the via fuse 124, the lower nanostructure FETs 10L are not part of active circuitry for the device as the upper nanostructure FETS 10U are being utilized to operate (e.g., switch in the high voltage to open or blow) the via fuse 124. Due to the stacked nature of the CFET device, the lower device could be inaccessible if the via fuse 124 is opened, and thus, the lower device is inactive. In these embodiments, the lower source/drain regions 62L and the lower gate stacks 86L are all connected to V_{DD}.

In some embodiments (not separately illustrated), the substrate from lower wafer 110L is removed and a backside interconnect is formed. In these embodiments, the buried conductive features 38 may be omitted and the V_{DD} and bit line connections can be made in the backside interconnect.

The embodiments of the present disclosure have some advantageous features. In accordance with some embodiments, a via fuse is formed, which is sometimes referred to as a deep via fuse, and the via fuse is included in a memory cell area of the device. One or more interlayer dielectric layers are etched to form an opening therein, followed by filling the opening to form a via fuse, which may be formed of metal. The via fuse may extend from a source/drain region to a buried conductive region in a substrate. The via fuse may be used as a fuse to remove or isolate devices from functional portions of a circuit. By including the via fuse in the CFET device, and in some embodiments in the memory cell area of the device, the area required for the fuses can be reduced and can save as much as 30% area over conventional fuse layouts. This reduced area size can increase the density of a CFET memory array using the disclosed structure, for example.

An embodiment includes a method including forming a first conductive feature and a second conductive feature in a substrate. The method also includes forming a first complementary field-effect transistor (CFET) over the substrate, the forming including forming a first lower transistor including a first gate and a first source/drain region. The method also includes forming a first upper transistor including a second gate and a second source/drain region, the first upper transistor overlapping the first lower transistor. The method also includes forming a conductive via fuse connected to the first conductive feature and the second source/drain region.

Embodiments may include one or more of the following features. The method where the conductive via fuse is adjacent the first lower transistor. The first and second conductive features are buried power rails. The first conductive feature is a bit line of a memory cell array. The method further including forming a conductive via connected to the second conductive feature and the first source/drain region. The conductive via fuse is longer than the conductive via. The first lower transistor is not part of active circuitry and the first gate, the first source/drain region, and the second conductive feature are all coupled to a power supply voltage VDD. The conductive via fuse is configured to function as a fuse for the CFET. The first lower transistor and the first upper transistor are formed by processes including forming the first lower transistor in a first wafer, forming the first upper transistor in a second wafer, and bonding the first wafer to the second wafer. The first upper transistor is formed after the first lower transistor has been formed.

An embodiment includes a structure including a first conductive feature and a second conductive feature in a substrate. The structure also includes a first complementary field-effect transistor (CFET) over the substrate, the CFET including a first lower transistor including a first gate and a first source/drain region. The structure also includes a first upper transistor including a second gate, a second source/drain region, and a first contact structure on the second source/drain region, the first upper transistor overlapping the first lower transistor. The structure also includes a conductive via fuse connected to the first contact structure and the first conductive feature.

Embodiments may include one or more of the following features. The structure where the first and second conductive features are buried power rails in the substrate. The first conductive feature is a bit line of a memory cell array. The structure further including a second contact structure on and connected to the first source/drain region, and a conductive via connected to the second contact structure and the first source/drain region, the conductive via fuse being longer than the conductive via. The structure further including a first interlayer dielectric over the second conductive feature and the first source/drain region, the conductive via fuse extending through the first interlayer dielectric. The first lower transistor is not part of active circuitry and the first gate, the first source/drain region, and the second conductive feature are all coupled to a power supply voltage VDD. The conductive via fuse is configured to function as a fuse for the CFET.

An embodiment includes a structure including a complementary field-effect transistor (CFET) including a first buried conductive feature and a second buried conductive feature in a substrate. The structure also includes a lower transistor including a first gate stack. The structure also includes a first source/drain region. The structure also includes a first contact structure on and connected to the first source/drain region. The structure also includes a first conductive via connecting the first contact structure and the first buried conductive feature. The structure also includes an upper transistor overlapping the lower transistor and including a second gate stack. The structure also includes a second source/drain region. The structure also includes a second contact structure on and connected to the second source/drain region. The structure also includes a second conductive via connecting the second contact structure and the second buried conductive feature.

Embodiments may include one or more of the following features. The structure where the second conductive via is configured to function as a fuse for the CFET. The second conductive via is longer than the first conductive via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a substrate;
a first transistor on the substrate;
a second transistor on the first transistor;
a buried conductive feature in the substrate;
a first conductive via connecting the second transistor to the buried conductive feature, wherein the first conductive via has a first length; and
a second conductive via connecting the second transistor to the buried conductive feature, wherein the second conductive via has a second length greater than the first length, and wherein the second conductive via is configured as a fusible link for circuit modification.

2. The semiconductor device of claim 1, wherein the first transistor and the second transistor form a complementary field-effect transistor (CFET).

3. The semiconductor device of claim 1, wherein the buried conductive feature is a power rail or a bit line.

4. The semiconductor device of claim 1, wherein the second conductive via extends through at least two dielectric layers.

5. The semiconductor device of claim 1, wherein the second conductive via comprises a liner layer and a conductive material.

6. The semiconductor device of claim 1, wherein the second conductive via has a width between 5 nm and 100 nm.

7. The semiconductor device of claim 1, wherein the second conductive via has a depth between 10 nm and 50 μm.

8. A method comprising:
forming a complementary field-effect transistor (CFET) structure including a lower transistor and an upper transistor overlapping the lower transistor;
forming a buried conductive feature in a substrate below the CFET structure;
forming a via fuse through one or more dielectric layers, wherein the via fuse connects a source/drain region of the upper transistor to the buried conductive feature; and
configuring the via fuse for post-fabrication circuit modification by changing the via fuse to a high resistance state.

9. The method of claim 8, wherein changing the via fuse to a high resistance state comprises applying a programming voltage to cause electromigration in the via fuse.

10. The method of claim 8, further comprising forming a liner layer in an opening before forming the via fuse.

11. The method of claim 8, wherein forming the via fuse comprises:
forming an opening through the one or more dielectric layers; and
filling the opening with a conductive material.

12. The method of claim 8, further comprising:
forming a contact on a sidewall and a top surface of the source/drain region of the upper transistor, wherein the contact is connected to the via fuse.

13. The method of claim 8, wherein the CFET structure comprises a plurality of semiconductor nanostructures for each of the lower transistor and the upper transistor.

14. The method of claim 8, wherein the buried conductive feature is a power rail or a bit line.

15. A method comprising:
forming an array of complementary field-effect transistors (CFETs), each CFET including a lower transistor and an upper transistor;
forming buried conductive features in a substrate for power distribution and signal routing;
forming programmable via fuses connecting source/drain regions of the upper transistors to the buried conductive features;
configuring the lower transistors to be inactive; and
connecting source/drain regions and gate stacks of the lower transistors to VDD, wherein the upper transistors are configured to operate the programmable via fuses.

16. The method of claim 15, wherein forming the programmable via fuses comprises:
forming openings through one or more dielectric layers; and
filling the openings with a conductive material.

17. The method of claim 16, further comprising forming a liner layer in the openings before filling the openings with the conductive material.

18. The method of claim 15, wherein the array of CFETs is part of a memory array, and the programmable via fuses are configured to isolate faulty memory cells from the memory array.

19. The method of claim 15, wherein the buried conductive features comprise a first buried conductive feature connected to a power supply node and a second buried conductive feature connected to a bit line node.

20. The method of claim 15, further comprising programming at least one of the programmable via fuses by applying a voltage to change the at least one programmable via fuse to a high resistance state.
